(19) United States
(12) Patent Application Publication
(10) Pub. No.: US 2002/0062727 A1
(43) Pub. Date: May 30, 2002

(54) Arrangements to virtualize ancillary sound configuration

(76) Inventor: David I. Poisner, Folsom, CA (US)

Correspondence Address: ANTONELLI, TERRY, STOUT & KRAUS, LLP, Suite 1800, 1300 North Seventeenth Street, Arlington, VA, 22209, US

(21) Appl. No.: 09/725,874

(22) Filed: Nov. 30, 2000

(51) Int. Cl. H03G 3/00; G06F 17/00; G11C 5/00; G10H 7/00

(52) U.S. Cl. 84/604; 700/94; 381/61

(57) ABSTRACT

Arrangements to virtualize an ancillary sound arrangement, e.g., a legacy speaker tone arrangement.

### FIELD

The present invention is directed to arrangements to virtualize an ancillary sound arrangement, e.g., a legacy speaker tone arrangement.

### BACKGROUND

Both a background and example embodiments of the invention will be described using a legacy sound arrangement, although practice of the present invention is not limited thereto.

The computer industry's devotion, commitment and adherence to support long existing legacy arrangements to maintain backwards compatibility of new platforms with old platforms, have advantageously helped fuel the wide-spread (i.e., global) acceptance of computers and the explosion of the computer industries. One such legacy platform arrangement is the use of a 8254 timer arrangement (e.g., the 8254/82C54 programmable interval timer manufactured by Intel Corporation of Santa Clara, Calif.) for generation of speaker tones.

More particularly, early in the history of computer development, speaker tones were provided for, and used, for example: to generate audio error tones/patterns for use in diagnostics when a computer system was unable successfully to boot, for generation of a speaker tone upon erroneous user input (e.g., responsive to user depression of a key which was unrecognized in the then present context), or for crude sound generation for early computer games. Such was provided for, for example, via the use of an 8254 timer arrangement, by dividing a standard clock signal into differing frequencies for application to a low-fidelity speaker for differing tones. In the present day computing world, there still may exist some old software and/or hardware arranged to generate tones via the expected 8254 timer/tone legacy arrangement. For example, a user may prefer or desire to run an older version of software, such as an early computer game.

Maintaining backwards compatibility of a new system's platform with old legacy platforms, likewise has resulted in disadvantages. With regard to platforms, new design innovation may be stymied and platform cost may be disadvantageously increased when required to provide and comply-with legacy platform specifications in addition to contemporary specifications. With regard to the 8254 timer/tone legacy arrangement, while a primary semiconductor area within a next generation IC (integrated circuit) chip may be devoted solely to contemporary sound arrangements, a significant amount of additional semiconductor area may also be required to provide additional “backwards compatibility” circuitry with respect to the 8254 timer/tone legacy arrangement. The problems are that the backwards compatibility circuitry uses valuable semiconductor area, and adds to the design complexity, pin count and size of the next generation processor IC chip. Increase in design complexity and/or pin count may significantly add to time-to-market (TtM) delays and may represent a significant cost or disadvantage of the chip. Increase in chip size and pin count contradicts the trend in the industry toward compactness.

### BRIEF DESCRIPTION OF THE DRAWINGS

The foregoing and a better understanding of the present invention will become apparent from the following detailed description of example embodiments and the claims when read in connection with the accompanying drawings, all forming a part of the disclosure of this invention. While the foregoing and following written and illustrated disclosure focuses on disclosing example embodiments of the invention, it should be clearly understood that the same is by way of illustration and example only and that the invention is not limited thereto. The spirit and scope of the present invention are limited only by the terms of the appended claims.

The following represents brief descriptions of the drawings, wherein:

FIG. 1 is an example block diagram of an example motherboard arrangement useful in understanding a background of the present invention;

FIG. 2 is an another example block diagram useful in understanding further background with respect to the present invention.

FIG. 3 likewise is an example which is useful in understanding background of the present invention.

FIG. 4 is an example block diagram of an example motherboard containing alternative example embodiments of the present invention.

### DETAILED DESCRIPTION

Before beginning a detailed description of the subject invention, mention of the following is in order. When appropriate, like reference numerals and characters may be used to designate identical, corresponding or similar components in differing figure drawings. Well known power/ground connections to ICs and other components may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits, flowcharts) are set forth in order to describe example embodiments of the invention, it should be apparent to one skilled in the art that the invention can be practiced without, or with variation of, these specific details. Finally, it should be apparent that differing combinations of hard-wired circuitry and software instructions can be used to implement embodiments of the present invention, i.e., the present invention is not limited to any specific combination of hardware and software.

Although example embodiments of the present invention will be described using an example system block diagram in an example personal computer (PC) environment, practice of the invention is not limited thereto, i.e., the invention may be able to be practiced with other types of systems, and in other types of environments (e.g., servers).

Turning now to detailed description, FIG. 1 illustrates an example block diagram of an example motherboard arrangement 100 useful in understanding a background of the present invention. More particularly, the motherboard 100 includes a processor unit (PU) 110 which may run software providing for generation of legacy speaker tones, for example: for use in diagnostics when the computer system containing the motherboard 110 is unable successfully to boot, for generation of a speaker tone upon erroneous user input, or for crude sound generation for early computer games. Upon a need to generate a speaker tone, PU 110 communicates with a timer 114 (e.g., the aforementioned 8254 timer well known in the industry, and manufactured by Intel Corporation of Santa Clara, Calif., as well as many differing integrated circuit (IC) manufacturers), via a communication path 112. The tone communication may be of any appropriate form, e.g., the communication may contain tone information instructing the frequency of tone which should be generated, may contain enable information instructing the time or periods that the tone should be output, amplitude information, etc. The timer 114 may contain a plurality of timer arrangements, and may, for example, contain a divider arrangement (not shown) which divides a frequency of a system clock (not shown) so as to generate a frequency of an instructed tone. The timer 114 outputs an appropriate frequency output on a speaker (SPKR) pin (not shown) and communication path 116 to a speaker 120. Although not shown within FIG. 1 as well as other FIGS., a well known voltage bias circuit (e.g., including one or more resistors, one or more transistors, etc.) may be provided along the communication path 116 between the timer 114 and speaker 120. The speaker 120 converts to a tone via electrical-to-mechanical conversion.

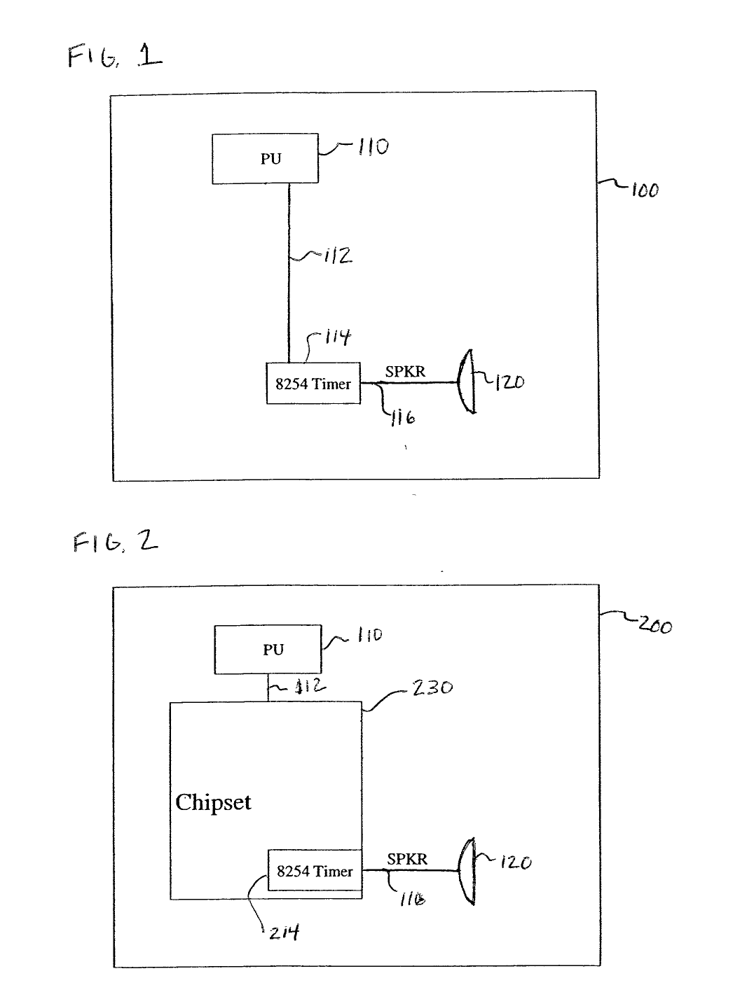

Turning next to FIG. 2, FIG. 2 illustrates an example block diagram of an example motherboard arrangement having a next stage of development in a background of the present invention. More particularly, within motherboard 200, components/arrangements which are similar to those of FIG. 1 have redundant discussion thereof omitted for sake of brevity. Within FIG. 2, the timer 214 is now provided as part of a chipset 230. More particularly, the timer 214 is provided as part of the chipset 230 in order to foster compactness and lessen design complexity and requirements of original equipment manufacturers (OEM's). More specifically, the chipset may integrate a plurality of different functions which were previously provided separately or discretely, with the timer 214 representing only one of such functions. The FIG. 2 arrangement allows generation of tones via the legacy 8254 timer/tone arrangement in a manner similar to that of FIG. 1, albeit with the 8254 timer 214 being provided and operating within the chipset 230 environment.

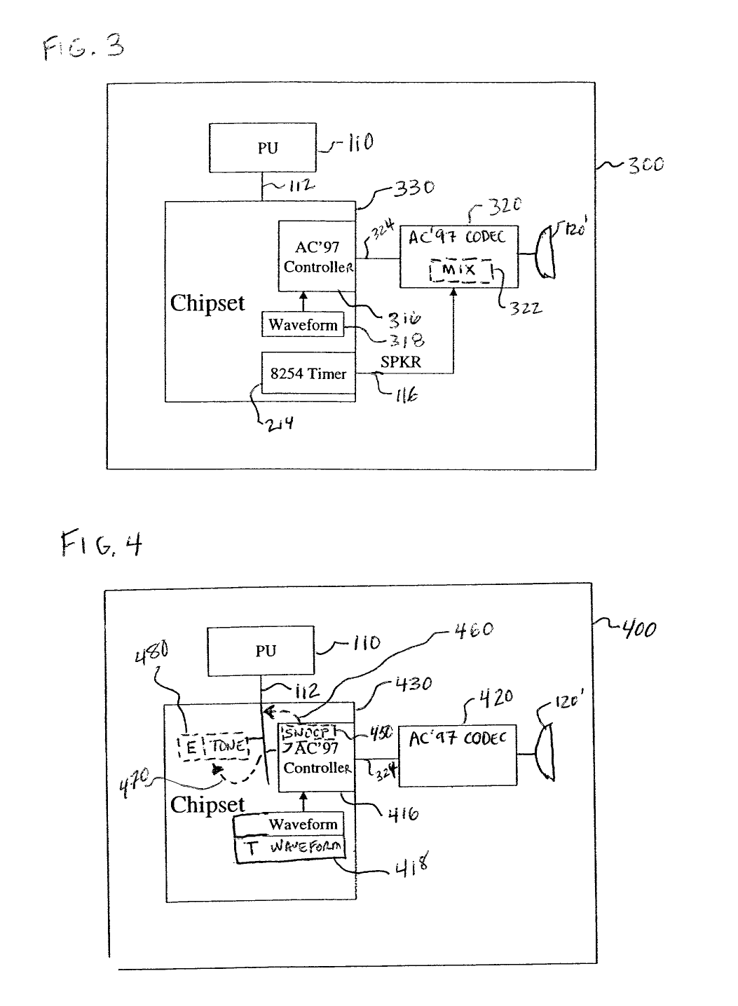

Turning next to FIG. 3, FIG. 3 is similar to the FIG. 2 arrangement, except that a contemporary Audio Codec (AC) '97 arrangement (e.g., in compliance with the AC '97 version 2.0 specification) has also been provided. Again, analogous or similar components are not redundantly discussed for sake of brevity. With regard to FIG. 3, in addition to the timer/tone legacy arrangement 214, the chipset 330 (manufactured by any independent hardware vendor (IHV)) includes an AC '97 compliant controller 316. A waveform library 318 accessible by the AC '97 controller may be provided anywhere within system memory, e.g., within a hard drive, flash memory, or even within specialized memory provided within the chipset 330. The audio codec (AC) '97 version 2.0 specification (announced Sep. 30, 1997), has arrangements enabling personal computers (PC's) with audio quality sound comparable to high-quality digital audio consumer electronic devices. The specification defines new cost-effective options to help PC OEM's integrate the components necessary to support next-generation audio intensive PC applications such as DVD, 3-D multiplayer games and interactive music. The AC '97 2.0 specification can be downloaded, for example, from the Intel website at developer.intel.com/PCSUPP/platform/AC '97.

Further included in the FIG. 3 arrangement is an AC '97 coder/decoder (codec) 320 receiving input from the AC '97 controller via communication path 324 and communication from the timer 214 via a speaker pin (not shown) and communication path 116. The AC '97 codec 320 provides output to the speaker 120′. Included within the AC '97 codec 320 is a mixer (MIX) 322 for allowing the analog input from the timer 214 to be mixed into the signal path within the codec 320.

Accordingly, with the FIG. 3 example arrangement, the PU 110 can generate legacy tones which are then provided to and serviced by the timer 214 and codec 320 arrangement, or provide contemporary sound via contemporary AC '97 instructions which are provided to and serviced by the controller 316, waveform library 318 and codec 320. The FIG. 3 is disadvantageous in that, while a primary semiconductor area within the chipset 330 and codec 320 may be devoted solely to contemporary AC '97 arrangements, a significant amount of additional semiconductor area may also be required to provide the additional backwards compatibles timer/tone legacy arrangement 214 as well as the mixer 322. Further, in the trend toward minimizing pins, the legacy speaker pin (not shown) on the chipset 330 is undesirous, and the communication path 116 between such speaker pin and codec 320 represents additional manufacturing steps and costs.

Discussion turns finally to FIG. 4 containing example alternative embodiments of the present invention. More particularly, FIG. 4 includes arrangements to virtualize the legacy timer/tone arrangement. More specifically, the FIG. 4 arrangement is somewhat similar to the FIG. 3 arrangement, and accordingly, redundant discussions of analogous or similar components are avoided for sake of brevity, i.e., only differences will be discussed.

As a first difference, a snoop arrangement 450 is added to the AC '97 controller 416. Any well-known snoop arrangement may be utilized. Further, a tone “(T) waveform” library portion is added to the AC '97 waveform library 418. The T waveform library portion may contain a library of waveforms which are useable separately or in combination with one another to emulate predetermined tones (e.g., a library of legacy tones). Just like the waveform library 318, the waveform library 418 may be provided anywhere within system memory, e.g., within a hard drive, flash memory, or even within specialized memory provided within the chipset 430.

In a first example embodiment, the snoop arrangement 450 snoops (shown representatively by the dashed line 460) the communication path 112 (e.g., a system bus) either periodically or continuously for the occurrence of a legacy tone instruction from the PU 110. Upon detection of a legacy tone instruction, the AC '97 controller utilizes the snooped information from the communication path 112 to determine a time or period of enablement of the tone, as well as a frequency of the desired tone, etc. Using the tone information, the AC '97 controller accesses the T waveform portion of the library 418 to obtain at least one corresponding waveform useable to emulate the instructed legacy tone, and using the time/period information, outputs the retrieved T waveform along the communication path 324 to the codec 420. Due to the snoop 450, and with the controller 416 and waveform library 418 virtualizing the function of the legacy timer/toner arrangement, note that: the timer 214 has been eliminated from the chipset 430, the mixer 322 has been eliminated from the codec 420, and the legacy speaker pin (not shown) and communication path 116 and communication path bias circuit (not shown) have also been eliminated. Such results in significant savings in semiconductor real estate and manufacturing steps/costs and lowers a physical complexity of the arrangement.

Thus, in the FIG. 4 example embodiment, the sound generation arrangement (including the chipset 430 and codec 420) is mainly adapted to generate sound according to primary sound instructions in the computing system (e.g., AC '97 compliant instructions), but is further adapted to virtualize sound for ancillary instructions (e.g., legacy 8254 timer/tone instructions) which differ from the primary sound instructions.

An alternative example arrangement is also shown within FIG. 4. More particularly, instead of the snoop arrangement 450 conducting the snoop 460 of the communication path 112, the snoop arrangements 450 instead performs a snoop (shown representatively by the dashed line 470) of a memory location shown representatively by the dashed blocks 480. More specifically, the processor unit 110 can be pre-programmed to know a predetermined memory location 480 which has been designated to receive legacy tone instructions. The memory location 480 may be a register, for example, within the chipset 430, or, alternatively, may be a designated memory location anywhere within system memory (not shown). Accordingly, upon encountering legacy software requiring generation of a legacy tone, the PU 110 stores the legacy tone instruction within the memory location 480.

The memory location may contain enablement (E) information pertaining to a time or period for tone generation, tone information (TONE) pertaining to a frequency and/or amplitude of a tone to be generated, etc. The snoop arrangement 450 may then periodically or continuously monitor the memory location 480 for stored legacy tone information. Some type of arrangement may also be made to allow the snoop arrangement 450 to distinguish between old/already-serviced legacy tone information within the memory location 480 and new such information, e.g., a service flag may be provided. The E information may be as simplistic as a single bit indicative that a tone should be presently generated, or may be more complex such as multi-bits indicative of more-complex timing or information. The tone information may be as simplistic as a single-bit to designate, for example, two differing tones, or again may be multi-bits to identify a greater number of differing tones.

The practice of snooping, and the elimination of the timer 214, are not required for practice of the invention, for example, the timer 214 may still be provided (either internally as part of the chipset 330 or 430, or as a discrete component) and instructed by the PU 110 for library for legacy tone (ancillary sound) generation, and the controller can monitor an output of, or be interrupted by, the timer 214. In such arrangement, the timer 214 may be connected to the controller 316 or 416, and the communication path 116 may be omitted. Upon a monitor or interrupt indication, an arrangement (hardware or software) could be used to read values programmed into the 8254 and to use such information to program the waveform to be sent by the controller 316 or 416.

In concluding, reference in the specification to “one embodiment”, “an embodiment”, “example embodiment”, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

This concludes the description of the example embodiments. Although the present invention has been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

For example, practice of the present invention is not limited to processor or chipset implementation. As but one example, an embodiment of the present invention may be provided as part of an application specific integrated circuit (ASIC). Further, practice of the present invention is not limited to virtualizing 8254 legacy tones or arrangements but instead may by useable to virtualize other types of tones, sounds or arrangements. Still further, embodiments of the present invention may be provided at least partially as part of many possible differing chipsets, with non-exhaustive examples including: a graphics chipset, a sound chipset, a bridge chipset, etc.

What is claimed is:

1. A sound generation arrangement for a computing system, comprising:
a predetermined sound generation arrangement to generate sound according to primary sound instructions implemented in the computing system;
a monitor arrangement to monitor for predetermined evidence of occurrence of ancillary sound instructions which differ from said primary sound instructions; and
an ancillary waveform library arrangement containing predetermined ancillary waveforms, and adapted to use said predetermined ancillary waveforms to emulate predetermined ancillary sounds responsive to an ancillary sound instruction as monitored by said monitor arrangement.

2. A sound generation arrangement as claimed in claim 1, wherein said monitor arrangement is a snoop arrangement adapted to snoop a predetermined communication path for occurrence of said ancillary sound instructions.

3. A sound generation arrangement as claimed in claim 1, wherein said monitor arrangement is a snoop arrangement adapted to snoop a predetermined storage location for occurrence of said ancillary sound instructions.

4. A sound generation arrangement as claimed in claim 1, wherein said monitor arrangement is arranged to monitor a state of an ancillary sound generation arrangement as indication of occurrence of said ancillary sound instructions.

5. A sound generation arrangement as claimed in claim 1, wherein said monitor arrangement is responsive to an interrupt as evidence of occurrence of said ancillary sound instructions.

6. A sound generation arrangement as claimed in claim 1, wherein said sound generation arrangement is adapted to operation in accordance with an Audio Codec (AC) '97 specification, and wherein said ancillary sound instruction is a pre-AC '97 sound instruction.

7. A sound generation arrangement as claimed in claim 1, wherein said sound generation arrangement is provided at least partially as part of a chipset.

8. A sound generation arrangement as claimed in claim 1, wherein said primary sound instructions are instructions in accordance with a contemporary sound specification, whereas said ancillary sound instructions are instructions with a legacy sound specification.

9. A chipset comprising:
a predetermined sound generation arrangement to generate sound according to primary sound instructions implemented in a computing system;
a monitor arrangement to monitor for predetermined evidence of occurrence of ancillary sound instructions which differ from said primary sound instructions; and
an ancillary waveform library arrangement containing predetermined ancillary waveforms, and adapted to use said predetermined ancillary waveforms to emulate predetermined ancillary sounds responsive to an ancillary sound instruction as monitored by said monitor arrangement.

10. A chipset as claimed in claim 9, wherein said monitor arrangement is a snoop arrangement adapted to snoop a predetermined communication path for occurrence of said ancillary sound instructions.

11. A chipset as claimed in claim 9, wherein said monitor arrangement is a snoop arrangement adapted to snoop a predetermined storage location for occurrence of said ancillary sound instructions.

12. A chipset as claimed in claim 9, wherein said monitor arrangement is arranged to monitor a state of an ancillary chip set as indication of occurrence of said ancillary sound instructions.

13. A chipset as claimed in claim 9, wherein said monitor arrangement is responsive to an interrupt as evidence of occurrence of said ancillary sound instructions.

14. A chipset as claimed in claim 9, wherein said sound generation arrangement is adapted to operation in accordance with an Audio Codec (AC) '97 specification, and wherein said ancillary sound instruction is a pre-AC '97 sound instruction.

15. A chipset as claimed in claim 9, wherein said primary sound instructions are instructions in accordance with a contemporary sound specification, whereas said ancillary sound instructions are instructions with a legacy sound specification.

16. A system comprising:
a predetermined sound generation arrangement to generate sound according to primary sound instructions implemented in the computing system;
a monitor arrangement to monitor for predetermined evidence of occurrence of ancillary sound instructions which differ from said primary sound instructions; and
an ancillary waveform library arrangement containing predetermined ancillary waveforms, and adapted to use said predetermined ancillary waveforms to emulate predetermined ancillary sounds responsive to an ancillary sound instruction as monitored by said monitor arrangement.

17. A system as claimed in claim 16, wherein said monitor arrangement is a snoop arrangement adapted to snoop a predetermined communication path for occurrence of said ancillary sound instructions.

18. A system as claimed in claim 16, wherein said monitor arrangement is a snoop arrangement adapted to snoop a predetermined storage location for occurrence of said ancillary sound instructions.

19. A system as claimed in claim 16, wherein said monitor arrangement is arranged to monitor a state of an ancillary system as indication of occurrence of said ancillary sound instructions.

20. A system as claimed in claim 16, wherein said monitor arrangement is responsive to an interrupt as evidence of occurrence of said ancillary sound instructions.

21. A system as claimed in claim 16, wherein said sound generation arrangement is adapted to operation in accordance with an Audio Codec (AC) '97 specification, and wherein said ancillary sound instruction is a pre-AC '97 sound instruction.

22. A system a claimed in claim 16, wherein said sound generation arrangement is provided at least partially as part of a chipset.

23. A system as claimed in claim 16, wherein said primary sound instructions are instructions in accordance with a contemporary sound specification, whereas said ancillary sound instructions are instructions with a legacy sound specification.

24. A sound generation arrangement for a computing system, comprising:
predetermined sound generation means for generating sound according to primary sound instructions implemented in the computing system;
monitor means for monitoring for predetermined evidence of occurrence of ancillary sound instructions which differ from said primary sound instructions; and
ancillary waveform library means for containing predetermined ancillary waveforms, and for using said predetermined ancillary waveforms to emulate predetermined ancillary sounds responsive to an ancillary sound instruction as monitored by said monitor means.

25. A sound generation arrangement as claimed in claim 24, wherein said monitor arrangement is a snoop means is for snooping a predetermined communication path for occurrence of said ancillary sound instructions.

26. A sound generation arrangement as claimed in claim 24, wherein said monitor arrangement is a snoop means is for snooping a predetermined storage location for occurrence of said ancillary sound instructions.

27. A sound generation arrangement as claimed in claim 24, wherein said monitor arrangement is arranged to monitor a state of an ancillary sound generation arrangement as indication of occurrence of said ancillary sound instructions.

28. A sound generation arrangement as claimed in claim 24, wherein said monitor arrangement is responsive to an interrupt as evidence of occurrence of said ancillary sound instructions.

29. A sound generation arrangement as claimed in claim 24, wherein said sound generation means is for operating in accordance with an Audio Codec (AC) '97 specification, and wherein said ancillary sound instruction is a pre-AC '97 sound instruction.

30. A sound generation arrangement as claimed in claim 24, wherein said sound generation means is provided at least partially as part of a chipset.

31. A sound generation arrangement as claimed in claim 24, wherein said primary sound instructions are instructions in accordance with a contemporary sound specification, whereas said ancillary sound instructions are instructions with a legacy sound specification.

32. A sound generation arrangement for a computing system, comprising:
a snoop arrangement to snoop for indication of occurrence of a predetermined legacy sound instruction; and
a legacy waveform library arrangement containing predetermined legacy waveforms, and adapted to use said predetermined legacy waveforms to emulate predetermined legacy sounds responsive to a snooped legacy sound instruction as snooped by said snoop arrangement.

33. A sound generation arrangement for a computing system, comprising:
a monitor arrangement to monitor for indication of occurrence of a predetermined legacy sound instruction; and
a legacy waveform library arrangement containing predetermined legacy waveforms, and adapted to use said predetermined legacy waveforms to emulate predetermined legacy sounds responsive to a legacy sound instruction indicated by said monitor arrangement.
